(19) United States
(12) Patent Application Publication
(10) Pub. No.: US 2022/0228811 A9
(43) Pub. Date: Jul. 21, 2022

(54) TITANIUM-BASED THERMAL GROUND PLANE

(71) Applicant: The Regents of the University of California, Oakland, CA (US)

(72) Inventors: Payam Bozorgi, Santa Barbara, CA (US); Carl D. Meinhart, Santa Barbara, CA (US); Marin Sigurdson, Goleta, CA (US); Noel C. MacDonald, Santa Barbara, CA (US); David Bothman, Santa Barbara, CA (US); Yu-Wei Liu, Goleta, CA (US)

(73) Assignee: THE REGENTS OF THE UNIVERSITY OF CALIFORNIA, Oakland, CA (US)

(21) Appl. No.: 13/685,579

(22) Filed: Nov. 26, 2012

Related U.S. Application Data
(63) Continuation-in-part of application No. 13/055,111, filed on Jan. 20, 2011, now Pat. No. 8,807,203.
(60) Provisional application No. 61/563,733, filed on Nov. 25, 2011.
(60) Provisional application No. 61/082,437, filed on Jul. 21, 2008.

(51) Int. Cl. F28D 15/04; B23P 15/26

(52) U.S. Cl. CPC F28D 15/04; B23P 15/26

(57) ABSTRACT

Titanium-based thermal ground planes are described. A thermal ground plane in accordance with the present invention comprises a titanium substrate comprising a plurality of channels, wherein the channels are oxidized to form nanostructured titania (NST) coated on the surfaces of the channels, and a vapor cavity, in communication with the plurality of titanium channels, for transporting thermal energy from one region of the thermal ground plane to another region of the thermal ground plane

### CROSS REFERENCE TO RELATED APPLICATIONS

This application claims the benefit under 35 U.S.C. Section 119(e) of the following co-pending and commonly assigned patent application which is incorporated by reference herein:

U.S. Provisional Patent Application Ser. No. 61/563,733, filed on Nov. 25, 2011, by Payam Bozorgi, Carl D. Meinhart, Marin Sigurdson, Noel C. MacDonald, David Bothman, and Yu Wei, entitled “TITANIUM-BASED THERMAL GROUND PLANE,” attorney's docket number 30794.441-US-P1.

This application is related to the following Patent Applications:

PCT International Patent Serial No. US2012/23303, filed on Jan. 31, 2012, by Payam Bozorgi and Noel C. MacDonald entitled “USING MILLISECOND PULSED LASER WELDING IN MEMS PACKAGING,” attorney's docket number 30794.405-WO-U1, which application claims priority to and benefit under 35 U.S.C. §119(e) of U.S. Provisional Patent Application 61/437,936, filed on Jan. 31, 2011, by Payam Bozorgi and Noel C. MacDonald entitled “USING MILLISECOND PULSED LASER WELDING IN MEMS PACKAGING,” attorney's docket number 30794.405-US-P1; and

U.S. Utility patent application Ser. No. 13/055,111, filed on Jan. 20, 2011 by Payam Bozorgi, Carl D. Meinhart, Changsong Ding, Gurav Soni, Brian D. Piorek, and Noel C. MacDonald entitled “TITANIUM BASED THERMAL GROUND PLANE,” attorney's docket number 30794.284-US-WO, which application claims priority to and the benefit under 35 U.S.C. §365(c) of PCT International Patent Application No. US2009/051285, filed on Jul. 21, 2009, by Payam Bozorgi, Carl D. Meinhart, Changsong Ding, Gurav Soni, Brian D. Piorek, and Noel C. MacDonald entitled “TITANIUM BASED THERMAL GROUND PLANE,” attorney's docket number 30794.284-WO-U1, which application claims priority to and benefit under 35 U.S.C. §119(e) of U.S. Provisional Patent Application 61/082,437 filed on Jul. 21, 2008, by Payam Bozorgi, Carl D. Meinhart, Changsong Ding, Gurav Soni, Brian D. Piorek, and Noel C. MacDonald entitled “TITANIUM BASED THERMAL GROUND PLANE,” attorney's docket number 30794.284-US-P1,

which applications are incorporated by reference herein.

### STATEMENT REGARDING FEDERALLY SPONSORED RESEARCH AND DEVELOPMENT

This invention was made with Government support under Grant No. W9113M-04-01-0001 and Grant No. W31P4Q-10-1-0010 awarded by the U.S. Army. The Government has certain rights in this invention.

### BACKGROUND OF THE INVENTION

1. Field of the Invention.

This invention relates to semiconductor devices, and, more particularly, to thermal ground planes (TGPs) used to cool semiconductor devices and other devices.

2. Description of the Related Art.

(Note: This application references publication(s) as indicated throughout the specification by one or more reference numbers within brackets, e.g., [x]. A list of these publication(s) ordered according to these reference numbers can be found below in the section entitled

“References.” Each of these publications is incorporated by reference herein.)

Electronics employing various semiconductor devices and integrated circuits are commonplace and are subjected to various environmental stresses. Applications of such electronics are extremely widespread, and utilize different semiconductor materials.

Operating environments for electronic devices can be extremely harsh. Large temperature changes, gravitational forces, and shock resistance are required for electronic devices to perform their functions properly. Further, as semiconductor processing and materials have advanced, semiconductor capabilities and heat dissipation have also increased.

Typical, semiconductor devices and integrated circuits are thermally bonded to heat sinks to dissipate heat generated by the semiconductor devices during operation. There are various problems with such approaches, such as ensuring such assemblies can survive the environmental and structural requirements of the operating environment and ensuring that the overall weight and size of the heat sink/device assembly fits within the design envelope of the application. Further, materials used for the heat sink must not adversely affect the device, even though the materials are dissimilar in terms of thermal coefficients of expansion. Such differences usually lead to more complex heat sink designs that are more difficult to incorporate into the application for the semiconductor devices.

Without loss of generality, the Thermal Ground Plane (TGP) can be used to cool semiconductor devices in a large range of applications, including but not limited to aircraft, satellites, laptop computers, desktop computers and data centers.

It can be seen, then, that there is a need in the art for cooling semiconductor devices.

### SUMMARY OF THE INVENTION

One or more embodiments of the present invention describe a Thermal Ground Plane (TGP) for cooling semiconductor devices, integrated circuits, high-power electronics, radar systems, laser radiation sources, and the like. The TGP is fabricated using Titanium (Ti) and Titania (TiO₂) processing technology, including forming Nano-Structured Titania (NST) in large-scale processes. Optionally, composite materials using high thermally -conductive materials can be used to increase thermal conductivity. These materials include but are not limited to gold, copper, and the like.

For example, one or more embodiments of the invention describe a thermal ground plane, comprising a titanium substrate comprising a plurality of channels, forming a wicking structure; a vapor cavity, in communication with the plurality of titanium channels; and a fluid contained within the wicking structure and vapor cavity for transporting thermal energy from one region of the titanium substrate or thermal ground plane to another region of the titanium substrate or thermal ground plane, wherein the fluid is driven by capillary forces or acceleration-induced body forces within the wicking structure.

In the wicking structure, a channel in the plurality of channels can comprise dimensions of 1˜500 μm depth, 1˜5000 μm width and spacing between the channels of 1˜500 μm. As heat is generated by a heat source thermally coupled to the one region of the titanium substrate:

(1) the wicking structure can transfer the heat to the fluid contained in the wicking structure in liquid phase and transform the fluid from liquid phase into vapor phase through latent heat of evaporation,

(2) the evaporation of the fluid from the wicking structure can create a void of the fluid in the liquid phase in the wicking structure, creating the capillary forces that draw the fluid through the wicking structure,

(3) the evaporation can create a pressure gradient comprising a higher pressure of vapor in the vapor cavity above the heat source and lower pressure of vapor in the vapor cavity above a heat sink thermally coupled to the titanium substrate and separated from the heat source,

(4) the vapor can be transported through the vapor cavity by the pressure gradient and the vapor condenses and returns to a liquid state above the heat sink, thereby releasing the latent heat of evaporation at a location of condensation near heat sink, and

(5) the condensed fluid in the liquid state can be transported through the wicking structure from the another region that is cooler and near the heat sink, towards the one region that is hotter and near the heat source, by the capillary forces or the acceleration-induced body forces, thereby completing a thermal transport cycle.

The channels and vapor cavity can have one or more dimensions and one or more compositions in contact with the fluid, such that a thermal conductivity of the thermal ground plane between the one region and the another region is at least 100 Watts per milliKelvin at a temperature gradient of at least 50 degrees Celsius between the one region and the another region.

The channels can comprise a rectangular cross-section with a rectangular opening at the top, extending from one side of the thermal ground plane to another side of the thermal ground plane.

The thermal ground plane can further comprise a second titanium substrate, wherein the vapor cavity is enclosed by the titanium substrate and the second titanium substrate. The second titanium substrate can be a titanium vapor cavity substrate backplane, and the second titanium substrate can be hermetically-sealed to the wicking structure by a pulsed laser micro-welding packaging technique.

At least one characteristic of each channel in the plurality of channels can be controlled to adjust the transport of thermal energy within the thermal ground plane. For example, the at least one characteristic can be selected from a group comprising a height of each channel in the plurality of channels, a depth of each channels in the plurality of channels, a spacing between each channel in the plurality of channels, an amount of oxidation of each channel in the plurality of channels, and a pitch of each channel in the plurality of channels.

The at least one characteristic of each channel in the plurality of channels can be varied within the plurality of channels.

At least a portion of the channels in the plurality of channels can comprise a composite of titanium with a thermally conductive material.

At least a portion of the channels in the plurality of channels can comprise a composite of titanium with at least one metal selected from gold and copper.

The thermal ground plane can comprise titanium feedthroughs fabricated on the Titanium thermal ground plane, wherein the titanium feedthroughs, of the second titanium substrate, are hermetically welded to the titanium substrate by pulsed laser micro-welding, and the second titanium substrate is a backplane and the titanium substrate is a wick plane.

The titanium channels in the wicking structure can be oxidized to form Nano Structured Titania (NST) on a surface of the channels. One or more embodiments of the present invention discloses the micro/nano scale processes that can be used to form NST, which is a super-hydrophilic wick material, deep etched titanium channels. An array of the Ti/NST channels forms a wicking structure for the TGP. The Ti or Ti/NST wicking structure can be tailored to the application by changing the density, position, pitch, spacing (or gap), and height of the deep etched titanium channels or pillars hereafter referred to as channels for brevity. In addition, the degree of oxidation can be used to tailor the wicking structure. Optionally, composite structures consisting of highly conductive materials can be used to further increase the thermal conductivity of the wicking structure.

Accordingly, one or more embodiments of the present invention comprises a titanium substrate (sheet) with an integrated array of titanium micro-scale channels of controlled dimensions, which can be coated with NST, and cavities to support the chips; the top sheet is micro laser welded to the titanium plate with channels (wick-plane). The dimension of the TGP is greatly scalable, and can be less than 1 cm×1 cm or greater than 40 cm×40 cm. The large TGPs can be fabricated, for instance, using wet etch or dry etch processes.

A thermal ground plane in accordance with one or more embodiments of the present invention comprises a titanium substrate comprising a plurality of channels of controlled dimension, wherein the plurality of channels are oxidized to form nanostructured titania in wick-plane, and a vapor cavity in the backplane in communication with the plurality of titanium channels, for conducting thermal energy from the titanium substrate.

A method of forming a thermal ground plane in accordance with the present invention comprises etching a titanium substrate to form a plurality of titanium channels and optionally oxidizing the titanium substrate to form nanostructured titania on the surface of titanium channels, and a titanium substrate suitably machined or etched forming a vapor cavity in communication with the titanium channels.

Such a method further optionally comprises the titanium substrate that can optionally be thinned in at least part of an area of the substrate opposite the plurality of the channels, the vapor cavity being enclosed using a second substrate which can be constructed from titanium, the titanium channels can be formed using the titanium deep wet etching technique, at least two characteristics of the plurality of channels can be controlled and optionally varied to adjust a thermal transport of the thermal ground plane, and the at least one characteristic being selected from a group comprising a depth, a width, a spacing (or a gap), an amount of oxidation, a pitch of the plurality of channels, and a composition of material(s) which may include but is not limited to Ti, TiO₂, Au, Al or Cu applied to the channels surface to control surface physical properties including wet-ability.

A thickness of the titanium substrate can be reduced to match thermally induced stresses of the titanium substrate with a semiconductor device thermally coupled to the titanium substrate (e.g., the thickness can be less than 100 micrometers, for example).Such a method further optionally comprises forming the TGP consisting of a composite structure of Ti/Au or Ti/Au/Ti or other suitable materials that can increase the thermal conductivity of the wicking structure.

### BRIEF DESCRIPTION OF THE DRAWINGS

Referring now to the drawings in which like reference numbers represent corresponding parts throughout:

FIG. 1 illustrate schematics (a) and (b) and a top view (c) of a preferred embodiment of the Ti-based thermal ground plane of the present invention;

FIG. 2 illustrates a schematic of an embodiment of the Ti-based thermal ground plane in accordance with one or more embodiments of the present invention;

FIG. 3 illustrates a schematic of the hermetic feedthroughs on the Ti-based thermal ground plane in accordance with one or more embodiments of the present invention;

FIG. 4 illustrates the patented packaging method used to seal the Ti thermal ground plane, wherein a millisecond YAG pulsed laser is used to micro-weld the titanium wickplane to the titanium backplane in accordance with one or more embodiments of the present invention;

FIG. 5 are scanning electron microscope (SEM) images of the titanium channels and the microstructure in accordance with one or more embodiments of the present invention, wherein (A) shows the wicking structure, (B) shows the dimensions that can be controlled including depth, width and spacing (denoted as gap, g), (C) and D are a close-ups showing the nano-structured-titania (NST) on the micro channels;

FIG. 6 illustrates cross sections at various stages of the fabrication steps used in accordance with one or more embodiments of the present invention;

FIG. 7 illustrates the fabrication process to grow NST on micro channel, wherein the achieved NTS films using the developed process on the channels are significantly stable and enhance the wetting properties of the channels in wick plane, in accordance with one or more embodiments of the present invention;

FIG. 8 illustrates a plot of characteristic wetting speeds achieved experimentally based upon different dimensions for the channels (depth, width and spacing gap), wherein the plot is used to determine the optimized dimension for the channels for the wick embodiment of the present invention;

FIG. 9 illustrates a plot that was achieved from experiment to compare the wetting speeds of the channels with pillars, wherein the plot shows that the channels improve the wetting speed of the wicks significantly when compared to pillars of similar dimension.

FIG. 10 illustrates a plot of effective thermal conductivity of the TGP as a function of heat loads for different orientation of TGP (0, 45 and 90 degrees illustrated by dark (or black) dots, green (or light gray) dots, and red (or dark gray) dots, respectively), in accordance with one or more embodiments of the present invention;

FIG. 11 illustrates a plot of effective thermal conductivity of the TGP as a function of temperature at the heat source for different orientation of TGP (0, 45 and 90 degrees, illustrated by dark (or black) dots, green (or light gray) dots, and red (or dark gray) dots, respectively) in accordance with one or more embodiments of the present invention;

FIG. 12 illustrates a flow chart of the formation of one or more embodiments of the Ti-based TGP in accordance with one or more embodiments of the present invention.

FIG. 13 illustrates a method of fabricating a TGP according to one or more embodiments of the invention.

### DETAILED DESCRIPTION OF THE INVENTION

In the following description of the preferred embodiment, reference is made to the accompanying drawings which form a part hereof, and in which is shown by way of illustration a specific embodiment in which the invention may be practiced. It is to be understood that other embodiments may be utilized and structural changes may be made without departing from the scope of the present invention.

Overview

Titanium is a material that is used in many applications that are subjected to harsh environments, including stealth systems and aerospace vehicles. Commercial applications for titanium include oil well drilling equipment, transportation, shipping, and chemical manufacturing. Titanium and titanium alloys can provide excellent bio-compatibility and have achieved broad acceptance for use in medical and biological applications, including hip replacements, dental implants, and packaging of implant devices, sensors and pacemakers. Micro-machined titanium substrates with integrated Nano-Structured Titania (NST) can also be used to make more robust, shock resistant Thermal Ground Planes (TGPs).

Micro-fabrication of Ti channels can be manufactured with controlled dimensions (depth, width, and spacing) to engineer the wicking structure to optimize performance and customize to specific applications. Titanium can be oxidized to form nanostructured titania (NST).

Titanium is a material that can be microfabricated using cleanroom processing techniques, macro-machined in a machine shop, and hermetically packaged using the pulsed laser micro welding technique. The combination of these manufacturing techniques creates a unique method for fabricating TGPs.

One or more embodiments of the present invention describe the fabrication of titanium-based Thermal Ground Planes (TGPs). One or more embodiments of the present invention can comprise two substrates (of which one or more can be constructed using titanium), one substrate supports an integrated super-hydrophilic wicking structure and a second substrate consists of a deep-etched (or macro-machined) vapor cavity that is laser micro welded to the wicking structure to form the TGP.

Schematic View

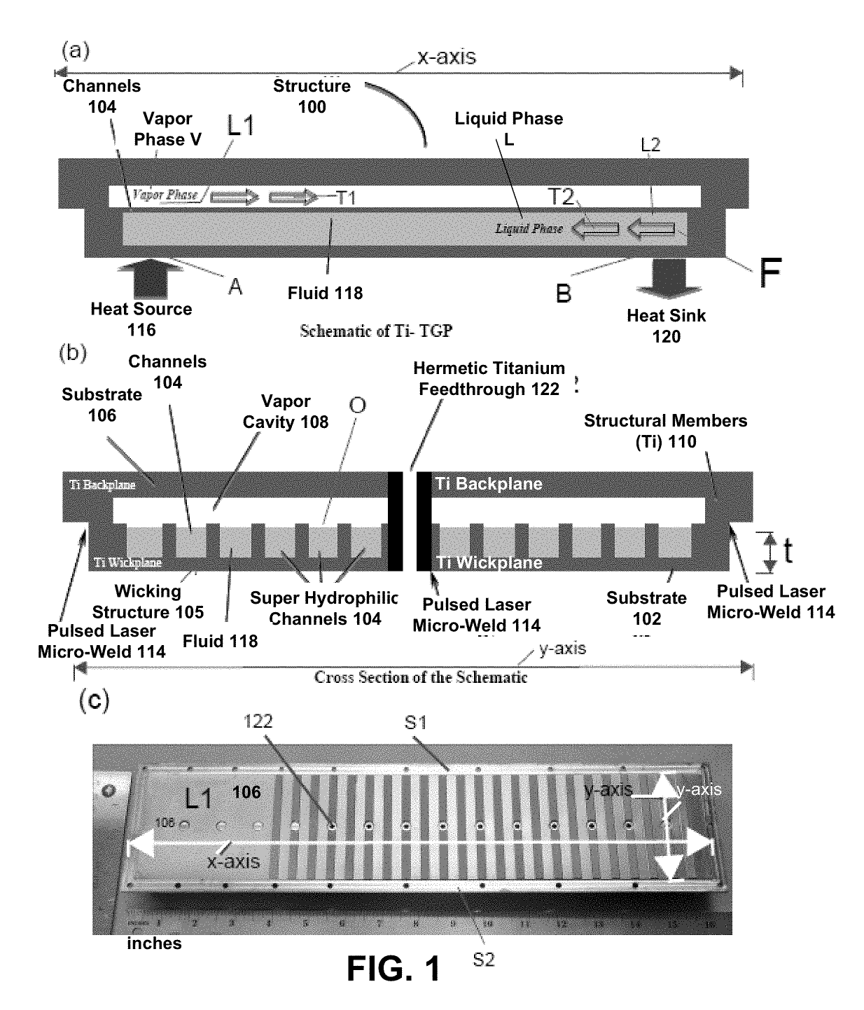

FIG. 1(a)-(c) illustrates schematic cross-sections and a top view of a preferred embodiment of the Ti-based thermal ground plane of the present invention.

The Thermal Ground Plane (100) of the present invention typically comprises a substrate (102), with channels (104) that form a wicking structure (105). Typically, the substrate (102) is titanium, and the characteristic dimension of the titanium substrate (102) is 25-1000 micrometers (or μm) thick, and can span 1 centimeter (cm)—more than 40 cm in the lateral dimension. In other embodiments, the substrate (102) are formed from other materials, such as but not limited to Al, Cu, Ag, and the like, either alone or as a composite with titanium.

Typically, the channels (104) are titanium, but can also be other materials in accordance with the present invention, including nano-structured titania (NST), a composite of titanium with other metals such as gold, aluminum or copper, or other materials either alone or as a composite with titanium. In the present description, the discussion is with respect to titanium channels (104).

The titanium-based channels 104 are typically nominally 1-500 microns in depth, and nominally 1-5000 microns in width. The spacing between the channels 104 (i.e. the gap) can be nominally 1-500 microns. These dimensions of the channels, e.g., depth, width, and spacing (or gap), are controlled and optionally varied within the plurality of channels within the TGP 100 in order to maximize TGP performance. For instance, the dimensions can be designed such that viscous losses are minimized and capillary forces are maximized in order to improve TGP performance. Although the dimensions, or characteristics, of the channels 104 can vary throughout the TGP 100, the characteristics can vary locally within the TGP 100 or can vary from one channel 104 to another channel 104, as desired for a given application or use of TGP 100, without departing from the scope of the present invention.

A second substrate 106, and structural members 110 (which can be part of either substrate 102, second substrate 106, or separate members 110), are combined to form a vapor cavity 108. The first substrate 102 is typically processed in accordance with the present invention to create the wicking structure 105. The first substrate 102 and second substrate 106 are, again, typically titanium, however, either substrate 102 or the second substrate 106 can be of a different material, or different materials than each other, if desired.

Typically, the structure 100 is ˜0.5-5 mm thick, but can be thicker or thinner depending on the desires of the designer or the design requirements of overall structure 100. The thickness of first substrate 102 is typically 25-1000 microns.

The super-hydrophilic 3D wicking structure 105 can also comprise titanium channels 104 and can be optionally coated with TiO₂ (Nano-Structured Titania). The channels 104 in the array 105 can be 350 μm in width and 200 μm in depth, however, the channels can be of different widths and depths depending on the design of structure 100, based on the heat transport characteristics desired or required by structure 100.

The channels can optionally be constructed from a composite of thermally conductive materials. These materials include but are not limited to Ti, TiO₂, Au, Al, Pt, or Cu applied to the channel surface to control surface physical properties including wettability. Typically, vapor cavity 108 is approximately 10-5000 μm thick, however, again, this thickness can vary depending on the desires for or requirements of structure 100. For example, wicking structure 105 thermal conductivities of >100 W/mK and wicking inertial force (g-force) of greater than 20 G's are possible with the present invention. The vapor cavity is sealed by second substrate 106, where second substrate 106 hermetically seals the volume described by vapor cavity 108. Hermetic sealing of less than 0.01% fluid loss per year at 100° C. is possible using the invented packaging technique of pulsed laser micro welding 114 of the wicking structure 105 to the second substrate 106, forming vapor cavity 108. The pulsed laser micro welding 114 can use one or more techniques described in PCT International Patent Serial No. US2012/23303 entitled “USING MILLISECOND PULSED LASER WELDING IN MEMS PACKAGING” and incorporated by reference herein in the cross-reference to related applications section above.

As heat 116 is generated by a heat source (for example by the electronic devices), first substrate 102 and wicking structure 105 transfer the heat to the fluid 118, typically water, contained in wicking structure 105 in liquid phase. Heat is transferred to the fluid 118, which transforms the fluid 118 from liquid phase into vapor phase through latent heat of evaporation, transferring the heat from heat source 116, which can be a semiconductor device, high-power electronics, radar systems, laser radiation sources, and the like, or other heat source. The evaporation of fluid 118 from wicking structure 105 creates a region void of liquid in wicking structure 105. This void of liquid creates a capillary force through surface tension or acceleration induced body force such as gravity that draws liquid through the wicking structure 105, and allows vapor to be transported within the vapor cavity 108 as a result of a pressure gradient (higher pressure of vapor in the vapor cavity 108 above the hot source 116 and lower pressure of vapor in the vapor cavity 108 above the heat sink 120). The vapor is transported through the vapor cavity 108. The vapor condenses and returns to a liquid state above the heat sink 120, thereby releasing the latent heat of evaporation at the location of condensation near heat sink 120. The liquid is then transported through the wicking structure 105 from the cooler region near heat sink 120 towards the hot region near the heat source 116, thereby completing the thermal transport cycle.

FIG. 1(a) illustrates a cross-sectional schematic along a width (x axis) of the TGP 100 separating the heat source 116 and heat sink 120.

FIG. 1(b) illustrates a cross-sectional schematic across the colder heat sink 120 region and along a length (y-axis) of the TGP 100 between Side 1 51 and Side 2 S2, showing that the liquid F or 118 can transported along the length of the channels 104 (into the page or plane of FIG. 1(b) from the cooler region B near heat sink 120 towards the hotter region A near the heat source 116.

FIG. 1(c) is a top view of the TGP illustrating the location of the x-axis and y-axis cross-sections illustrated in FIG. 1(a) and FIG. 1(b).Similarly, structure 100 can be designed to transfer heat out of structure 100, e.g., act as a cooling source at one area of structure 100. For example, and not by way of limitation, the heat sink 120 can act as a removal area of heat for a device attached in that area, and the heat source 116 can remove of the heat transferred through vapor cavity 108. In essence, structure 100 can transport thermal energy in either direction, or act as a constant temperature source, for devices attached to structure 100, as desired.

The thickness of substrate 102 can be varied to be thinner at the location of heat source 116 and thinner at the location of heat sink 120, and thicker in other regions, which can be used for increased heat transfer efficiency, as a mounting location or indicia for the heat source 116, or other reasons, such as increasing structural integrity, as desired for the application of structure 100. The varied thickness of substrate 102 can also facilitate thermal matching, by reducing thermally-induced stresses imparted by substrate 102 to devices mounted to the TGP. So, for example, thermal matching of 10% for GaAs, Si and GN using the 25 μm thick substrates to support the semiconductor devices is possible within the scope of the present invention. This relatively small thickness of substrate 102 can be supported by thicker beams or channels/pillars that extend from first substrate 102 to second substrate 106 through the vapor cavity 108, if such support is necessary for a given heat source 116. Further, a larger portion or the entirety of substrate 102 can be thinned to any desired thickness to increase thermal transfer if desired or needed for a given application of structure 100.

The TGP 100 is formed by attaching the titanium substrate to a structural backplane, which can be manufactured from a variety of materials. In a preferred embodiment, the structural backplane can be machined from a second titanium substrate 106. The machining process could either be micro-machining (e.g. wet or dry etch) or macro-machining In a preferred embodiment, the structural backplane is wet etched from a titanium substrate.

Again, the vapor cavity 108 typically spans the lateral dimension of the working portion of the TGP 100, but can take various forms as desired. In a preferred embodiment, the vapor cavity 108 can have a depth of 100 microns to 10 millimeters, with a nominal thickness of 500 microns-5 millimeter. Judicious design of the wicking structure 105 allows for high mass flow rates of fluid 118 to be transported and thereby large amounts of heat to be transported. For example, large depth and large spacing of the channels 104 will reduced viscous losses. In addition, smaller spacing of the channels 104 will increase capillary forces. Judicious choices of these parameters throughout the TGP 100 will provide optimum TGP 100 performance for a given application of TGP 100.

In some embodiments, the titanium channels 104 should be oxidized to form nano-structured titania (NST). NST is used to increase wettability and thereby increase capillary forces, and enhance heat transfer, within TGP 100. As shown in FIG. 1, structure 100 comprises substrate 102 having a thickness of 500 microns, channels 104 having a depth of 200 microns, a vapor cavity 108 having a height of 1.5 mm above the channels 104, and a second substrate 106 having a thickness of 200 microns. These are typical heights and thicknesses for structure 100, and structure 100 can comprise other heights and thicknesses without departing from the scope of the present invention.

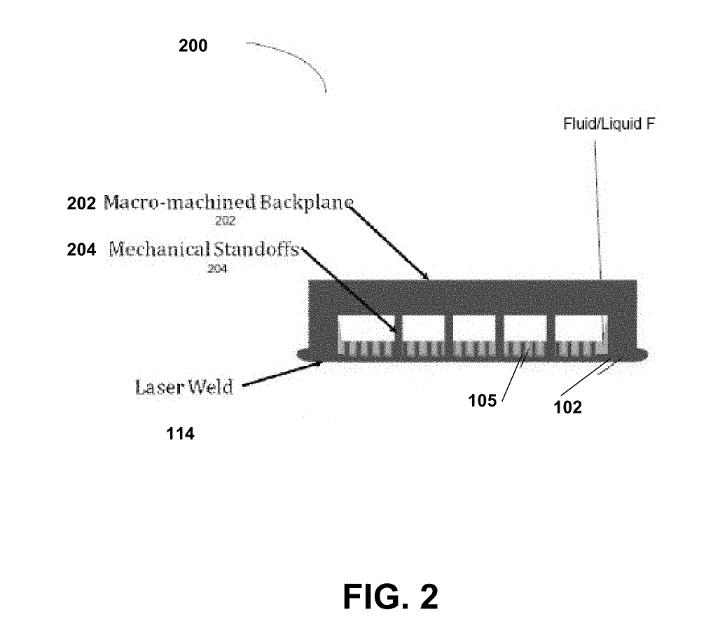

FIG. 2 illustrates a schematic of an embodiment of the Ti-based thermal ground plane in accordance with one or more embodiments of the present invention.

In structure 200, backplane 202, which is typically macro-machined (or wet or dry etched), but can be formed using other methods described herein, comprises the mechanical standoffs 204 in cold side of TGP and feedthroughs, and is attached to substrate 102 to enclose wicking structure 105 and vapor cavity 108. Typically, backplane 202 is laser micro-welded 114 to a micro-fabricated wicking structure 105 on substrate 102, and mechanical standoffs 204 are macro-machined on the backplane substrate 102. Mechanical standoffs 204 can be designed to increase the structural integrity of structure 200, which can be important for TGPs 200 with large lateral dimensions. Further, the use of mechanical standoffs 204 provides for additional engineering of substrate 102, including thinning substrate 102, since mechanical standoffs 204 allow for additional support of substrate 102 throughout the structure 200. FIG. 2 also illustrates the liquid or fluid F in the wicking structure 105.

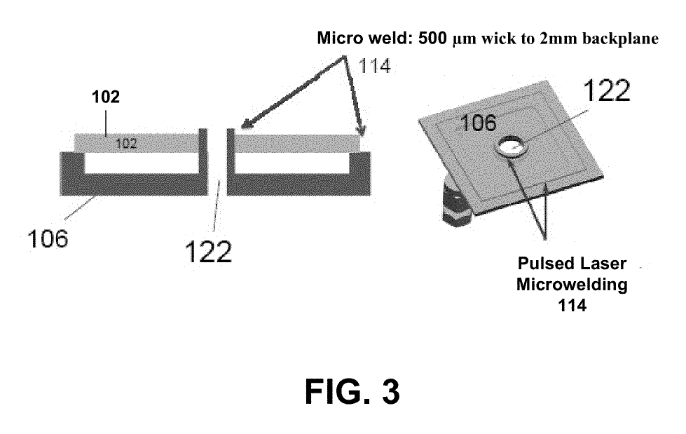

FIG. 3 illustrates a schematic of the fabricated hermetic Ti feedthroughs 122 on the Ti thermal ground plane 100 in accordance with one or more embodiments of the present invention.

The Ti feedthroughs 122 have a diameter of 8 mm and are macro-machined on the Ti backplane 106. The feedthroughs 122 are micro-welded 114 to the 500 micron thick wick plate 102 using the pulsed laser micro-welding packaging technique.

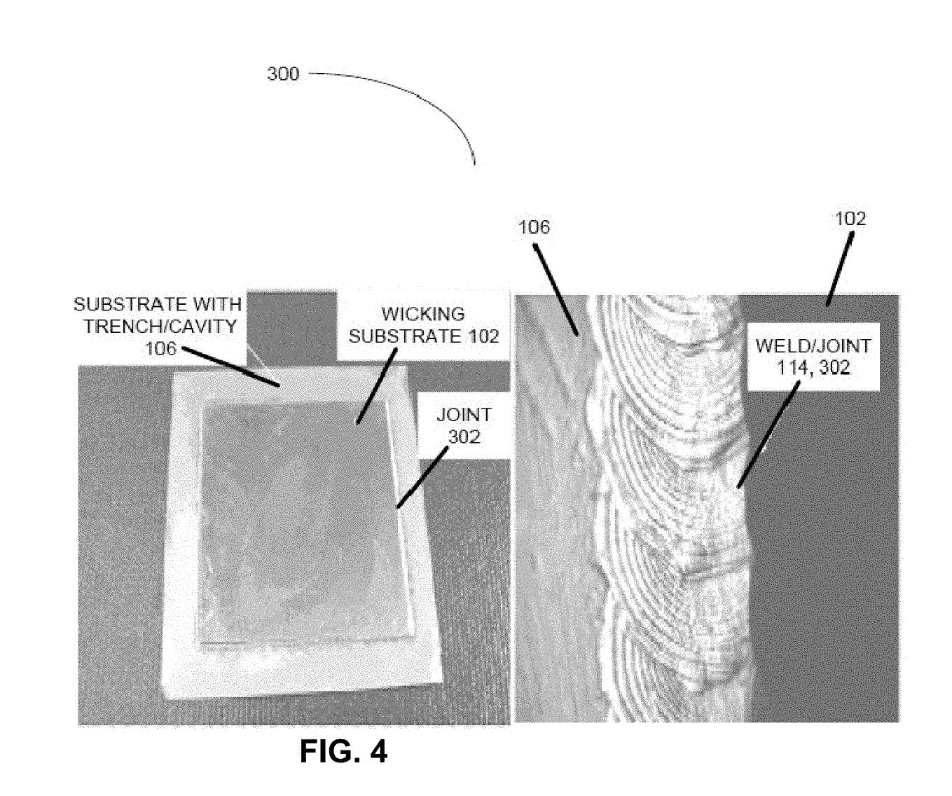

FIG. 4 illustrates a picture of a laser welded Ti thermal ground plane in accordance with one or more embodiments of the present invention.

Structure 300 is shown, where wicking substrate 102 and joint 302 is shown between wicking substrate 102 and a second substrate 106 is shown. The second substrate 106 consists of the trench or cavity. Joint 302 is typically a laser weld 114, as shown in detail, to hermetically seal substrate 102 to second substrate 106 and form vapor cavity 108.

For continuous operation, the working fluid and the wicking structure must be in communication with a vapor cavity and sealed such that the internal mechanism of the thermal ground plane 300 is isolated from the external environment to avoid vapor loss and system contamination. The performance of the TGP 300 therefore significantly depends on the quality of packaging. A major problem with conventional packaging techniques for such structures, such as high-temperature thermo-compression and flip chip bonding, is the degradation of reliability caused by the excess stress due to thermal mismatching. To eliminate the stresses which occur at high temperature, laser welding 114 is used to rapidly apply heat at a small region of the joint 302 instead of heating the entire device to hermetically weld the titanium.

In one embodiment, a millisecond pulsed wave YAG laser (Neodymium-Doped Yttrium Aluminum Garnet, Nd:Y3Al5O12) with a wavelength of 1064 nm can be used to micro weld the backplane 106 to the substrate 102. Such a laser can be focused to a very small area, for example 350 microns in diameter, to locally heat the material to the melting point. Given sufficient laser power and linear translation speed, for instance 1.8 J by 14 Hz pulse frequency, the substrate 102/backplane 106 joint 302 is welded yet the total energy absorbed is quickly dissipated by the bulk material such that nearby regions of the substrate 102/backplane 106 remain physically unaffected by the heat injected into the device by the welding process.

SEM Images

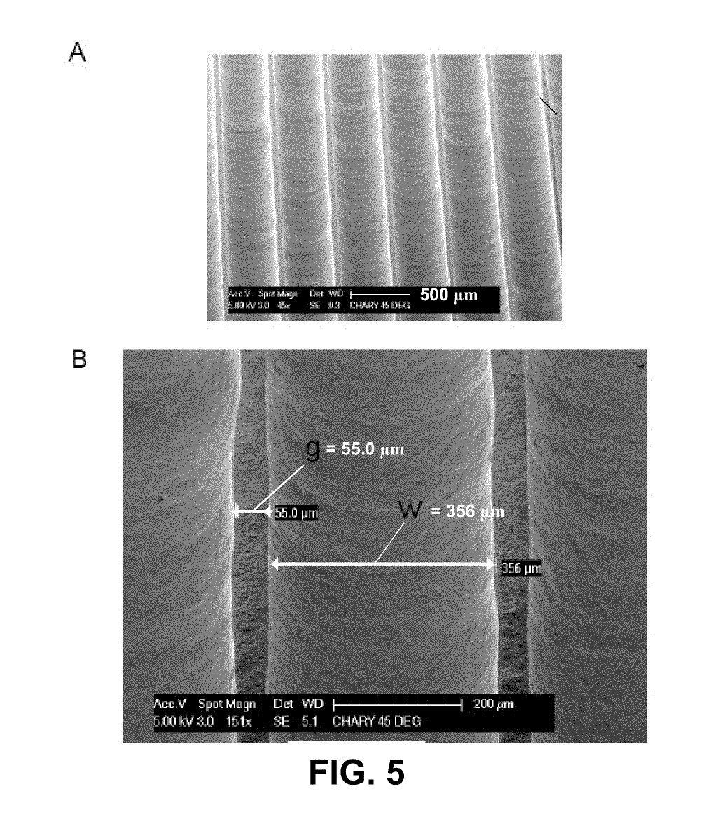

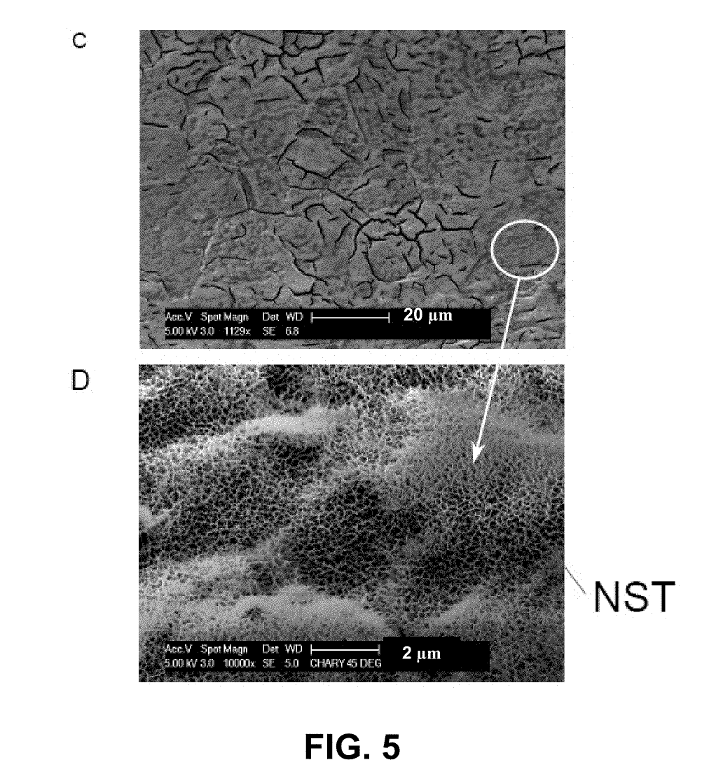

FIG. 5 are scanning electron microscope (SEM) images of the titanium channels microstructure in accordance with one or more embodiments of the present invention.

FIG. 5A shows channels 104 in an array structure to create an embodiment of wicking structure 105. As shown in FIG. 5B, the width “w”, spacing or gap “g”, and height “h” are fairly uniform, however, width w, gap g, and height h of the channels 104, individually, locally, or collectively can be controlled and/or optionally varied within the structure 100 plurality of channels to optimize the performance of the TGP 100.

The channels 104 are arranged in an array such that the width w, spacing g, and/or height h between the channels 104 are controlled and optionally varied to allow sufficient liquid 118 flow velocity through the channels 104. The flow velocity of liquid 118 is controlled by reducing viscous losses while simultaneously providing optimal surface area in order to draw the fluid 118 at a proper speed from the cool region 120 to the hot region 116 of the resulting TGP 100. Optionally, acceleration-induced body forces such as gravity can be used to drive fluid motion. Since the evaporation, adiabatic, and condensation regions of the TGP 100 perform separate functions within the TGP(evaporation, vapor and liquid phases of fluid 118 transport, and condensation, respectively), the channel geometry, composition, and distribution can be specifically designed to perform optimally in each of these regions. Further, the channels 104 in the wicking structure 105 can be in an array format, or in any random, pseudo-random, or otherwise structured design without departing from the scope of the present invention.

FIGS. 5C and 5D show SEM images of nanostructured titania (NST) etched into a channel 104. The channel 104 is oxidized to produce hair-like NST with a nominal roughness of 200 nanometers (nm). Other embodiments may include NST with a nominal roughness of 1-1000 nm. The hair-like NST structure enhances the wetting properties of Ti channels 104 which increases the working fluid 118 wetting performance within the wicking structure 105, and the overall heat transport properties of the TGP 100.

Array Processing

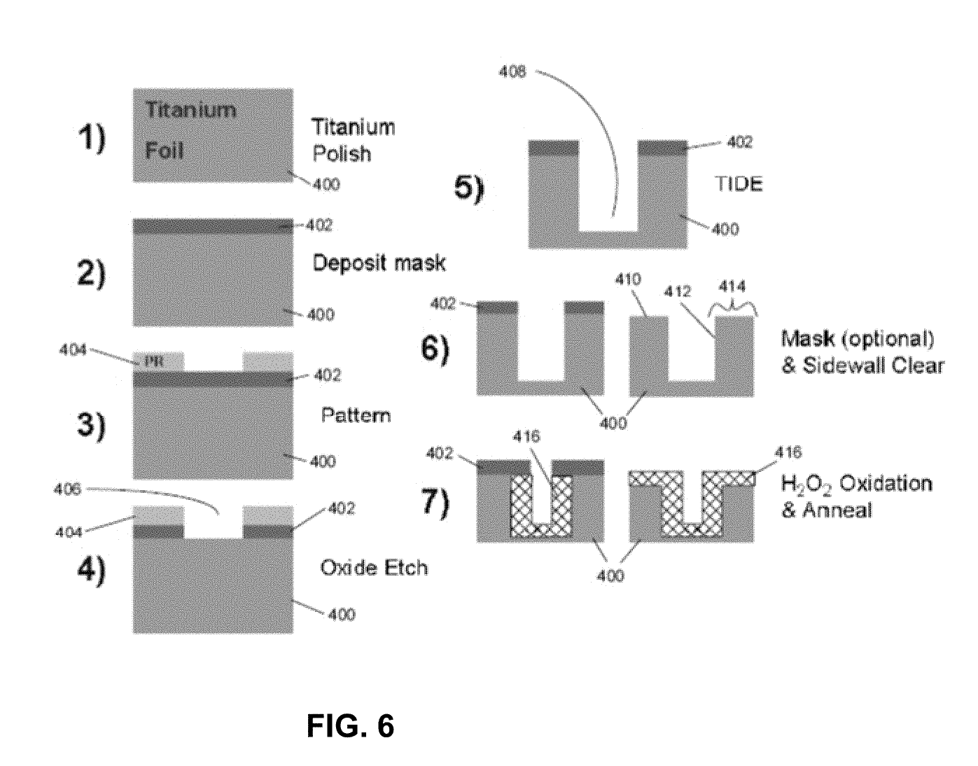

FIG. 6 illustrates side-views at various stages of typical processing steps used in accordance with the present invention.

Step 1 shows a bulk titanium wafer 400, which is polished sufficiently to allow for the desired lithographic resolution. Step 2 illustrates a masking material 402 that is deposited and patterned. Step 3 illustrates a pattern defined on the surface of masking material 402 using a photoresist 404, and step 4 illustrates an etching 406 to transfer the pattern into the masking material 402.

Step 5 illustrates deeply wet etching the substrate 400 using etch 408.

The TIDE process that can be used to etch is described in [1]“Titanium Inductively Coupled Plasma Etching” by E. R. Parker, et al., J. Electrochem. Soc. 152 (2005) pp. C675-83, which is incorporated by reference herein.

Step 6 illustrates masking material 402 being removed from substrate 400. Masking material 402 must be removed if formation of NST is desired on the top surface 410 of substrate 400. Likewise, if NST features are desired on sidewalls 412, etch mask products must be cleared from the sidewalls 412. However, if the formation of NST is not desired on top surface 410, then mask 402 can be left in place if desired. Channels 414 are now defined within substrate 400.

Step 7 illustrates substrate 400 being oxidized, and forming the NST on the top and side surface of the channels.

The aspect-ratio (depth to width) of channels 414 and the pitch (angle of the channels 414 with respect to the substrate 400) can be controlled by etching profiles and techniques, and the hydrophilic capabilities of each channels 414 can be controlled by the amount and/or depth of NST 416 formed on each channel 414, e.g., whether the NST 416 is formed on the top surface 410, how long the channels 414 are oxidized, etc.

NST Forming Processing

Forming the NST on the surface of the titanium channels is an important factor for the invented Ti based thermal ground plane. The NST makes the surface of the channels to be extremely hydrophilic, consequently improves the wetting velocity of the water inside of the channels. The coated surfaces by NST increase the wetting velocity by 70% compare to non-coated NST surfaces. Characteristic speeds can be of order centimeters per second. The titanium wick structure is cleaned in Nano-Strip to remove the organic residues off the substrates. The NST is formed by dipping the titanium structure in hydrogen peroxide between 80° C.-85° C. The NST 416 is then formed on the surfaces of the channels 414 of substrate 400. The titanium wick-plane is annealed at 300° C. for 60 minutes to accomplish NST forming. The wick is cleaned using high power Deep Ultraviolet lights right before packaging the wick to the backplane.

Composite channels Structure

One or more embodiments of the present invention comprise an alternative composite channels structure

Channel 104 is shown, which typically comprises titanium. Channels 104 can be surrounded by a highly thermally conductive material, such as but not limited to Au or Cu. Optionally, an outer layer 416 can be added to control wettability, such as but not limited to Ti or nanostructured titania. The use of material and/or outer layer provides flexibility in controlling thermal conductivity and wetting characteristics in the wicking structure 105 independently.

In the hot and cold regions of the TGP 100, heat transfer between the working fluid and the TGP is affected by the thermal conductivity of the channels 104 in these regions. Since overall TGP 100 performance is improved by a) improving the wetting speed of the working fluid 118, and b) improving the heat transfer properties of the channels array 105, these parameters can be optimized independently to optimize TGP performance.

Since wetting speed can be improved by providing a super hydrophilic surface on the surface of the channels 104, a rough surface such as that arising from oxidized Ti NST 416 can be added to each channel 104 as shown in FIG. 6. However, since neither NST nor Ti provides optimal heat conduction through the volume which they comprise, a material layer of Au or other material of improved heat transfer properties can be in communication with the Ti or NST outer layer 416 to improve the heat transport properties of each channel 104.

Materials providing improved channel 104 heat transfer properties can be added by, for example, thermal evaporation processes such as those driven by either tungsten filament heaters or electron beam sources; molecular beam epitaxy, chemical vapor deposition processes, or electroplating processes, or other methods.

In another embodiment, a Ti/NST layer can be added to a channel 104 consisting entirely of Au or other heat-conducting material. In another embodiment, a Ti/NST layer can be added to a microcomposite structure comprised at least partially of Au or Cu or other thermally-conducting material.

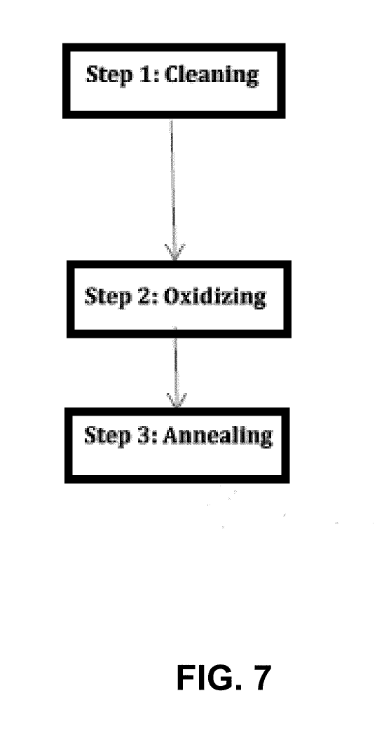

FIG. 7 illustrates the fabrication process to grow NST on a micro channel in accordance with one or more embodiments of the present invention.

Step 1 comprises cleaning the titanium wick plane 102. The cleaning can comprise using acetone and isopropanol solutions, removing organic residues by immersing the titanium wickplane into nanostrip solution at 70° C. for 30 seconds, and drying out the wickplane using nitrogen gas.

Step 2 comprises oxidizing the cleaned titanium wickplane. The oxidizing can comprise oxidizing the titanium wickplane in hydrogen peroxide (H₂O₂) by 30% concentration at the temperature of 85° C. for 20 minutes, and drying out the wickplane gently using nitrogen gas.

Step 3 comprises annealing the oxidized wickplane, e.g., at 300° C. for 60 minutes.

The achieved NTS films using the developed process on the channels are significantly stable and enhance the wetting properties of the channels in wick plane in accordance with one or more embodiments of the present invention.

Wetting Speeds

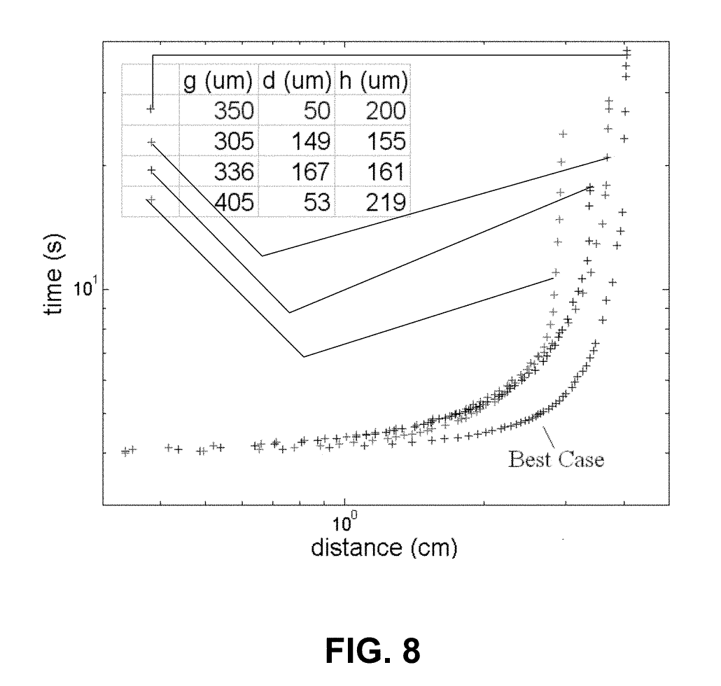

FIG. 8 illustrates a plot of characteristic wetting positions in channels plotted against time (vertical axis), for different dimensions for the wick embodiment of the present invention. Different depths (h), widths (d) and gaps (g) for channels are numerically and experimentally investigated to determine the optimize the channel dimensions. In this configuration, the wick structure is vertically dipped into a liquid reservoir. Higher wetting velocities are determined by wetting a larger distance in the least amount of time (i.e. curves to the bottom right).

FIG. 8 illustrates the optimized dimensions for the channels are 200 μm depth, 350 μm width and 50 μm gap between channels. The optimized dimensions maximize the wetting velocity of the working fluid inside of the channels. Characteristic speeds are of order centimeters per second.

Heat transport from the hot to cool region of the TGP 100 is provided by evaporation of liquid-phase fluid 118 into vapor-phase fluid 118, and the transport of vapor-phase fluid 118 from hot region 116 to the cold region 120 of the substrate 102. Simultaneously, the liquid-phase of fluid 118 is transported through wicking structure 105 from cold region 120 to hot region 116, which results from capillary forces, thereby completing the fluid transport cycle for transport of heat through the TGP. The wetting speed of fluid 118 through wicking structure 105, coupled with the height 308 of the wicking structure 105, determines the rate of mass transfer of fluid 118, and therefore the maximum rate at which heat can be transported through the TGP 100.

The heat transfer properties of the TGP 100 are therefore affected by the wetting speed of liquid-phase fluid 118 through wicking structure 105 (which is in communication with wicking substrate 102), whereby higher wetting speeds provide higher thermal transport of the TGP 100.

The wetting speed through wicking structure 105 was determined by observation. Wetting speed follows the Washburn equation which describes the associated wetting dynamics for the case of θ=0°, where θ is the angle of the TGP 100 with respect to the horizontal (perpendicular to the gravitational field direction). The wetting speed decreases with increasing wetting distance x as expected, due to increasing viscous resistance as the wetting path becomes larger. The NST-coated channels 104 improve substrate wetting speed over the entire range of wetting distance x in comparison to channels 104 which are not coated with NST. This indicates the application of NST to the channels will improve the heat transport properties of the TGP.

Channels vs. Pillars for Wicks

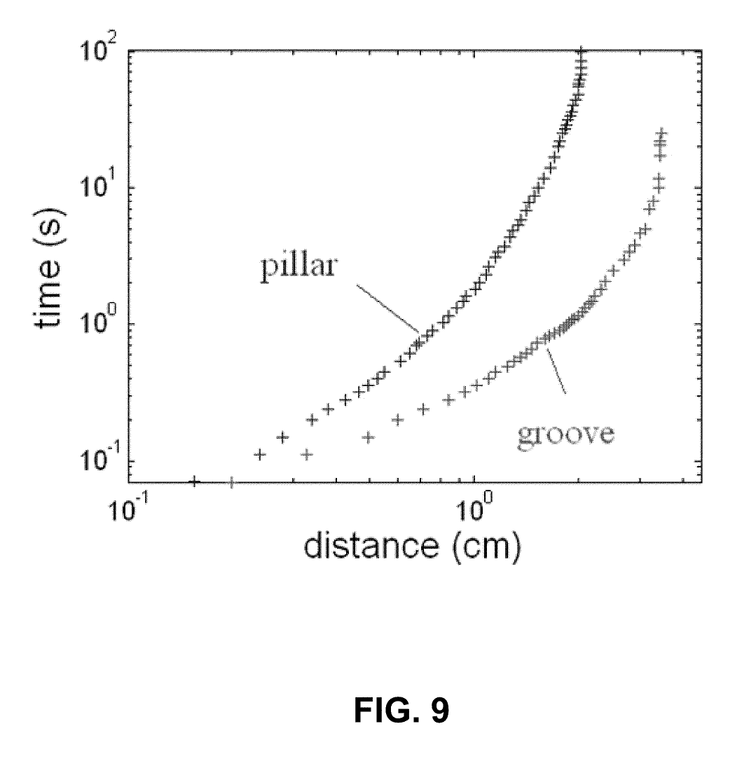

FIG. 9 illustrates the channels as a preferred wicking structures for the Ti-based thermal ground plane of one or more embodiments of the present invention. [Note in FIG. 9 the word ‘groove’ refers to ‘channel’.]

FIG. 9 illustrates a plot to compare the wetting velocity for channels and pillars. Plotting wetting time in seconds as a function of distance in centimeters. The experimental results on pillars and channels show that the wetting velocity of water inside of the channels is significantly faster than pillars. The pillars have dimension of 185 μm in diameter, 90 μm in height, and a 185 μm gap between pillars in the array and the channels have dimensions of 200 μm, 350 μm and 50 μm for channel's depth, width and gap respectively.

TABLE 1
showing the advantage of using channels to enhance
the heat flux capacity of the Ti thermal ground plane.

| | Qmax at 60 C. |
|---|---|
| Pillar, d = 185 um, g = 268 um, h = 90 um | 12.9 Watts |
| Channel, d = 50 um, g = 350 um, h = 200 um | 143 Watts |

Table 1 is a table to compare the heat load capacity for channels and pillars. The numerical simulation shows that the maximum heat capacity Qₘₐₓ for the TGP (assuming a θ=zero degree orientation) that used channels for wicking water is 143 W at 60 ° C., while for the case of using pillars the heat flux is 12.9 W for the similar temperature.

The wick structures in Ti-based thermal ground planes is of the “Pillars” type, which is essentially a plurality of columns that extend into the fluid. The wick structure of one or more embodiments of the present invention is of the “Channel” type, which improves the effective thermal conductivity of the TGP from approximately 300 W/K.m to 2,000 W/K.m (assuming zero degree orientation). Further improvements in thermal conductivity to 10,000-12,000 W/K.m results from orientating the TGP with respect to gravity at 45 and 90 degree angles. In addition, the fabrication process used in one or more embodiments of the present invention is more efficient than that used in pillar-based designs or other material-based ground planes.

Effective Thermal Conductivity

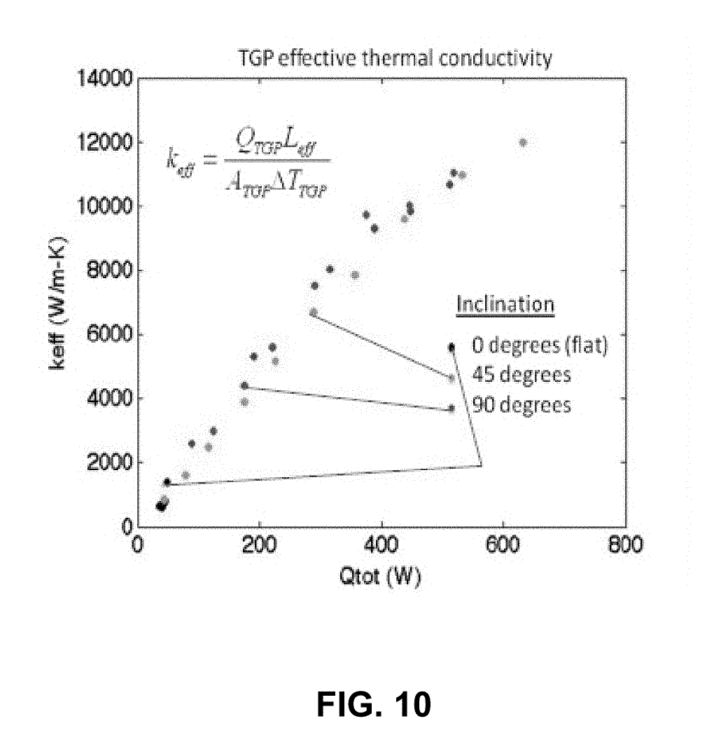

FIG. 10 illustrates a plot of the effective thermal conductivity K_{eff} of the TGP as a function of the heat source for 0°, 45 and 90° orientation in accordance with one or more embodiments of the present invention.

The graph shows heat carrying capacity of a TGP 100 embodiment comprised of Ti channels 104 coated with NST, and was evaluated by holding the hot region (i.e. hot side) 116 of the TGP 100 for several heat fluxes. Effective thermal conductivity k_{eff} of the TGP 100 increases as the heat flux is increased on the hot region (side) 116 of the TGP 100.

This demonstrates that the TGP 100 of the present invention can achieve at least 12,000 W/m-K of effective thermal conductivity.

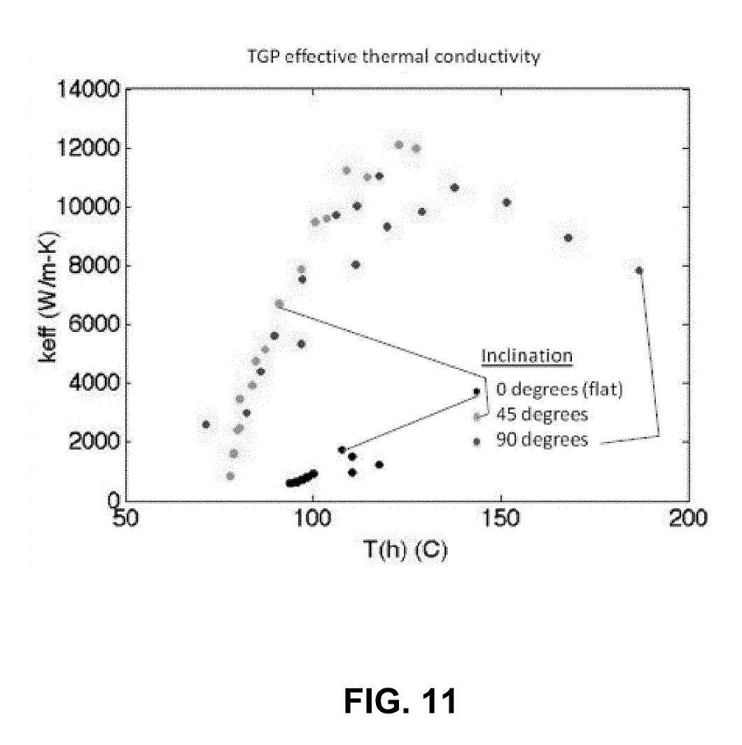

FIG. 11 illustrates a plot of the effective thermal conductivity of the TGP as a function of temperature for 0°, 45 and 90° orientation in accordance with one or more embodiments of the present invention.

The graph shows heat carrying capacity of a TGP 100 embodiment comprised of Ti channels 104 coated with NST, and was evaluated by holding the hot region (i.e. hot side) 116 of the TGP 100 at several temperatures while maintaining the temperature of the cold region (i.e. cold side) 120 of the TGP 100 constant (at 20° C.). Effective thermal conductivity k_{eff} of the TGP 100 increases as temperature is increased on the hot region (side) 116 of the TGP 100. In the depicted TGP 100 configuration, heat pipe ‘dryout’ occurs at temperatures greater than 140 ° C. for the 90° orientation. Dryout occurs due to the lack of capillary-driven flow of liquid-phase fluid 118 through wicking structure 105 sufficient to replenish the evaporated fluid 118 at hot region 116. By varying the design parameters of the TGP 100, including channels 104 depth 304, width 308, and spacing 306, the dryout temperature and overall heat carrying capacity of the TGP 100 can be optimized for various applications. In one embodiment, at least one parameter of the TGP 100 design can be controlled and optionally varied within the plurality of channels 104 to increase or decrease the dryout temperature to match a particular application. In another embodiment, at least one parameter of the TGP 104 design can be controlled and optionally varied within the plurality of channels 104 to increase or decrease the overall heat carrying capacity of the TGP to match a particular application.

Modeling of the Invention

The performance of the NST wicking structure and the packaged TGP has been modeled using computer software. The TGP of the present invention uses nano-scale NST coated Ti channels as the wicking structure. The distribution and density of the channels 104 that form the wicking structure 105 are variables that determine the performance of the TGP structure 100. By using simulation and modeling for a number of channels-array designs, the present invention can produce designs that deliver optimal effective thermal conductivity across the entire wicking structure, or optimized for specific locations of one or a plurality of hot regions 116 and one or a plurality of cold regions 120 on substrate 102.

Numerical simulations of the capillary-driven fluid motion, vapor-phase transport, heat transfer, and stress analysis was performed using COMSOL Multiphysics (COMSOL, Stockholm, Sweden) finite element software. The capillary-driven fluid motion through the NST wicking structure 105 was modeled using surface tension, the Navier-Stokes equation, and continuity. The level-set method was used to model the liquid/vapor interface. The rate of liquid evaporation multiplied by the heat of vaporization was balanced with the heat adsorbed inside the TGP. This rate was used as a sink term for the conservation of mass equation of the liquid phase, and as a source term for the conservation of mass equation of the vapor phase.

The driving force for flow through wick structures comes from capillary pressure. An expression for the capillary pressure can be obtained by comparing the difference in surface energy between wetted and dry areas. The expression of capillary pressure ΔP_{cap} for the channel wick structure is:

$$Δ {P}_{cap} = \frac{γ}{hg} [ cos θ ( g + 2 h ) - g ] \qquad ( 1 )$$

where γ is the surface tension, h is the channel height, g is the channel width.

The Navier-Stokes equations for flow in rectangular open channel are analytically solved. The flow is assumed to be unidirectional and no slip boundary conditions are used at the walls. Darcy's law is applied to obtain the permeability. To estimate the maximum heat transfer rate \dot{Q}_{heat, max} of the TGP, the pressure and drag in both liquid and vapor flows are calculated. The change of flow rate from evaporation and condensation is considered to calculate the total pressure drop. The maximum heat transfer rates can be obtained by balancing the total pressure drop and the capillary pressure:

$${\dot{Q}}_{heat , max} = \frac{\frac{2}{L} [ Δ {p}_{cap} + ( {ρ}_{f} - {ρ}_{g} ) {g}_{x} L ]}{[ ( {μ}_{f} {\tilde{β}}_{f} / {h}_{f} {K}_{f} + {μ}_{g} {\tilde{β}}_{g} / {h}_{g} {K}_{g} ) ]} \qquad ( 2 )$$

Where L is the total length of the TGP, ρ is density, gₓ is gravity, μ is viscosity, \tilde{β}=1/ρh_{fg}w, h_{fg} is latent heat, w is the total width of the TGP, and K is permeability, f subscript stands for fluid and g subscript stands for vapor (gas) such that h_{f, g} is latent heat, h_{f} is the depth of the fluid in the etched channel, and h_{g} is the vapor chamber depth.

Two reasons show the channel wick is better than pillar wick. First, the channel wick can provide higher capillary pressure because of the greater surface area, which increases the surface energy and the capillary pressure. Second, it is easier to make a deeper channel wick. The viscous drag will reduce in deeper channel wick.

The vapor-phase transport was modeled using the Navier-Stokes equation. At the cool end of the TGP, the rate of condensation divided by the heat of evaporation was balanced by the rate of condensation and the source/sink terms for the mass conservation equations of the liquid/vapors phases, respectively. The temperature distribution was modeled using the energy conservation equation. The simulation model was correlated with experiments to understand transport mechanisms. The results can be used to optimize the performance of the TGP for a variety of geometries and operating conditions.

Simulations on thermal mismatch were also performed to determine the suitability of a given TGP design for a specific application. The thermal expansion coefficients (TEC) for semiconductor materials vary significantly, for example (in units of 10⁻⁶/° C). Silicon is 2.6, GaAs is 6.9, and GaN is 3.2. Unfortunately, the TECs do not match well with potential conducting materials for TGPs, e.g., titanium (Ti) is 8.5, copper (Cu) is 13.5, and aluminum (Al) is 23. In order to minimize thermally-induced stresses between the TGP and the semiconductor-based device, it is desirable to match the TEC between the TGP and the chip within 1%.

The TECs are material specific. In principle, it may be possible to design a TGP that thermally matches one semiconductor, such as Si, however, it would be very difficult to design a universal TGP that can match several different semiconductor materials simultaneously. Instead of matching TECs directly, the present invention uses an alternative approach that universally reduces thermally induced stresses for all semiconductor materials, simultaneously.

The induced stress from two dissimilar materials bonded together can be approximated to first order (Eq. 3) by: (a) assuming the materials do not bend appreciably, (b) matching the total strain (i.e. the strain due to thermal expansion and the strain due to normal stress), and (c) equating equal and opposite forces due to normal stresses, such as σ₁t₁=−σ₂t₂, where σ₁ & σ₂ are the normal stress from material 1 & 2 (represented by subscripts 1 and 2 respectively), respectively. The thickness of materials 1 & 2 are denoted by t₁ & t₂, respectively.

The normal stress of material 1 is given by

$${σ}_{1} = ( {α}_{2} - {α}_{1} ) Δ {T [ \frac{1}{{E}_{1}} + \frac{1}{{E}_{2}} \frac{{t}_{1}}{{t}_{2}} ]}^{- 1} \qquad ( 3 )$$

where E is the elasticity module and a is the thermal expansion coefficient. As an example, if material 1 is the semiconductor chip, and material 2 is the TGP, for a given temperature change, ΔT, the normal stress in the semiconductor can be reduced by a number of factors. Clearly, one way to reduce σ₁ is to reduce the thermal mismatch, (α₂-α₁).

However, the present invention utilizes another method, which is to reduce thermally-induced stresses by maximizing the ratio t₁/t₂. Since Ti is a ductile material, with moderate strength, and is durable and corrosion resistant, it can be micromachined with ˜25 μm thick layers that interface with the semiconductor chip, while maintaining structural integrity. This not only provides efficient heat conduction from the chip to working fluid inside the TGP, but dramatically decreases thermal stresses, for all types of semiconductor materials simultaneously.

Considering a challenging scenario, where the temperature difference is ΔT=50° C., and assuming a t₁=500 μm thick Si wafer (chip 110) is bonded to a t₂=1 mm thick solid Cu TGP. From Eq. (1), the induced thermal stress in the Si chip would be σ₁=54 MPa. By comparison, the same t₁=500 μm thick Si wafer bonded to a t₂=25 μm thick Ti sheet (first substrate 102) would induce a thermal stress in the Si chip of σ₁=1.5 MPa, which is a 36 fold reduction in stress, compared to the solid 1 mm thick Cu substrate.

For reference, σ₁=1.5 MPa is the same level of thermally-induced stress that a 1 mm thick Cu substrate would impart on the same Si chip, if its effective TEC was only α_{eff}=2.8, which is similar (within 8%) to the actual TEC for Si, α_{Si}=2.6. Further, the titanium sheet would weigh less than the comparable copper thermal ground plane, which makes the approach of the present invention more desirable in applications where weight is a factor, e.g., space flight. Similar results are derived for other semiconductor materials. The effective TEC of the t₁=25 μm Ti TGP for GaN (α_{GaN}=3.4) is α_{eff}=3.4 (i.e. matches GaN to within 6.3%). Similarly, the effective TEC of the Ti TGP for GaAs (α_{GaAs}=6.9) is α_{eff}=7.03 (i.e. matches GaAs to within 1.8%).

In order to access the applicability of Eq. (1) to describe the thermally-induced stresses that our proposed Ti-based TGP would impart on a Si chip, a 2-D numerical simulation was conducted (COMSOL Multiphsyics V3.3; COMSOL, Inc., Stockholm, Se) to estimate a typical temperature distribution in the TGP.

Process Charts

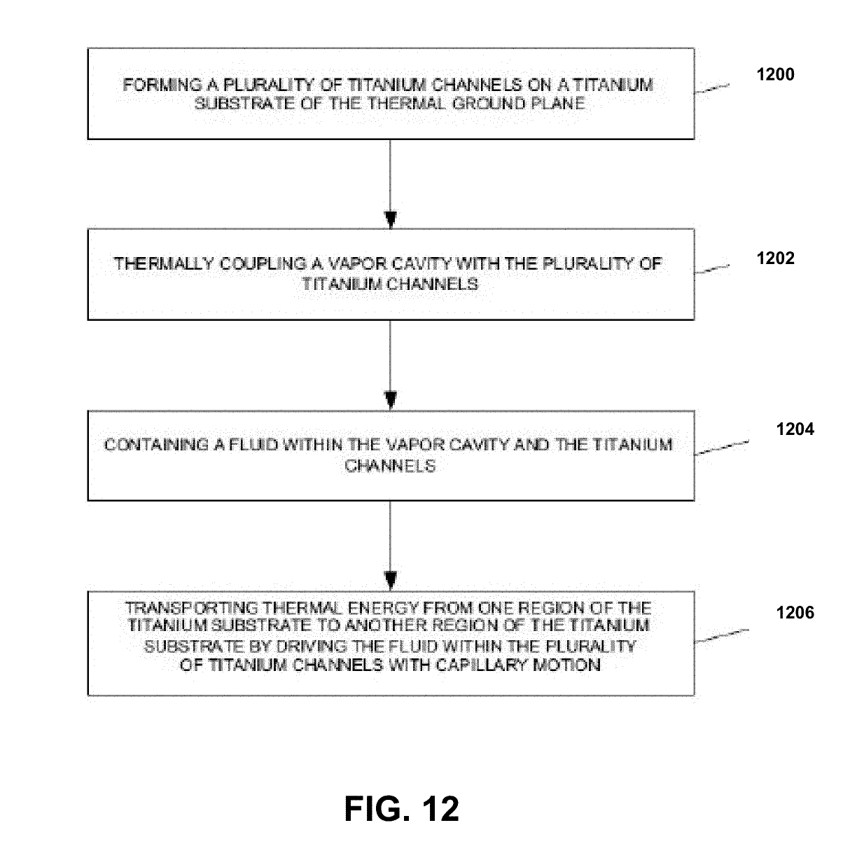

FIG. 12 illustrates a flow chart of the formation of one or more embodiments of the Ti-based TGP in accordance with the present invention.

Box 1200 illustrates forming a plurality of titanium channels on a titanium substrate.

Box 1202 illustrates thermally coupling a vapor cavity with the plurality of titanium channels.

Box 1204 illustrates containing a fluid within the vapor cavity and the titanium channels.

Box 1206 illustrates transporting thermal energy from one region of the titanium substrate to another region of the titanium substrate by driving the fluid within the plurality of titanium channels with capillary motion.

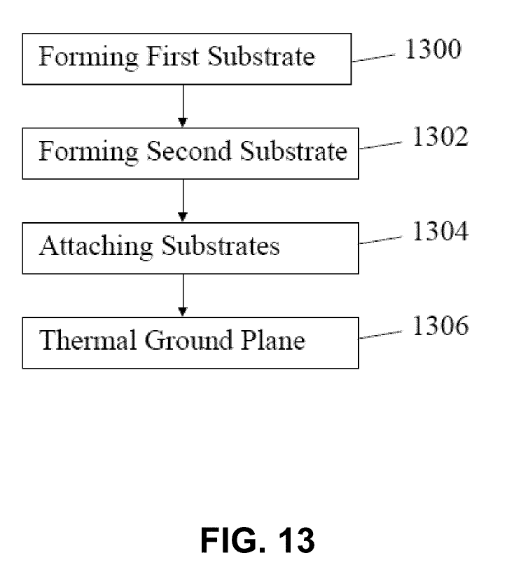

FIG. 13 illustrates a method for making a thermal ground plane (also referring to FIG. 1). The method can comprise one or more of the following steps.

Box 1300 represents forming a first substrate 102 including a plurality of titanium channels 104 on the first titanium substrate 102, member, plate, or sheet of the thermal ground plane, to form the wicking structure 105 or structure that creates capillary forces. The first substrate 102 can comprise, include, consist, or consist essentially of titanium, for example. The channels 104 or structures can be structured and have a composition to transport thermal energy from one region of the first titanium substrate 102 or thermal ground plane to another region of the titanium substrate or ground plane by driving a fluid within the plurality of titanium channels with capillary motion or acceleration-induced body force such as gravity.

The channels 104 can comprise a rectangular cross-section with a rectangular opening O at the top of the channel, extending from one side Si of the thermal ground plane to another side S2 of the thermal ground plane (see FIG. 1).

At least one characteristic of each channel in the plurality of channels can be controlled to adjust the transport of thermal energy within the thermal ground plane. The at least one characteristic is selected from a group comprising a height of each channel in the plurality of channels, a depth of each channels in the plurality of channels, a spacing between each channel in the plurality of channels, an amount of oxidation of each channel in the plurality of channels, and a pitch of each channel in the plurality of channels. The at least one characteristic of each channel in the plurality of channels can be varied within the plurality of channels.

At least a portion of the channels in the plurality of channels can comprises a composite of titanium with a thermally conductive material.

At least a portion of the channels in the plurality of channels can comprise a composite of titanium with at least one metal selected from gold and copper.

For example, a channel in the plurality of channels cam comprise dimensions of 1˜500 μm depth, 1˜5000 μm width and spacing between the channels of 1˜500 μm.

For example, the titanium channels in the wicking structure can be oxidized to form the NST on a surface of the channels. The NST can form titanium nano wires and prose with dimension of 100˜200 nm in diameter and they can increase the surface ratio of the channels to their volume remarkably.

Box 1302 represents forming a second substrate 106 including a vapor cavity 108 in the second titanium substrate, member, plate or sheet. The second substrate 106 can comprise, include, consist, or consist essentially of titanium, for example.

Box 1304 represents attaching the first and second titanium substrates to hermetically seal or enclose the vapor cavity 108 and structure (e.g., wicking structure 105) within or by the titanium substrates 102, 106 or members, thereby thermally coupling a vapor cavity 108 with the plurality of titanium channels 104 and containing a fluid F within the vapor cavity 108 and the titanium channels 104. The second titanium substrate 106 can be a titanium vapor cavity substrate backplane hermetically-sealed to the wicking structure and by a pulsed laser micro-welding packaging technique.

The attaching can be such that titanium feedthroughs 122 are fabricated on the Titanium thermal ground plane 100, wherein the titanium feedthroughs, of the second titanium substrate, are hermetically welded to the titanium substrate by pulsed laser micro-welding, and the second titanium substrate is a backplane and the titanium substrate is a wick plane.

Electrical feedthroughs can be to communicate (power up and read out) the chips that are mounted on the wick plate and/or to save significant space for wiring up/or connections to the chips and consequently, make the system more compact.

The feedthroughs are fabricated in the same manner that the TGP is fabricated. The feedthrough's fabrication is comprises of three steps: (a) fabricating the feedthroughs on the backplane (122, in FIG. 3) (b) fabrication the holes on wick plate (106, in FIG. 3) during the etching process and (c) packaging the wick plate on the backplane (106 and 102, in FIG. 3) using micro laser welding method to hermetically seal them together (114, FIG. 3)

Box 1306 represents the end result of the method, a device such as a thermal ground plane as illustrated in FIG. 1. The thermal ground plane can comprise a titanium substrate comprising a plurality of channels, forming a wicking structure; a vapor cavity, in communication with the plurality of titanium channels; and a fluid contained within the wicking structure and vapor cavity for transporting thermal energy from one region of the titanium substrate or thermal ground plane to another region of the titanium substrate or thermal ground plane, wherein the fluid is driven by capillary forces or acceleration-induced body forces such as gravity within the wicking structure.

The channels 104, the vapor cavity 108, and the attaching of the first substrate 102 to the second substrate 106 can be such that, as heat is generated by a heat source 116 thermally coupled to the one region A of the titanium substrate 102:

(1) the wicking structure 105 transfers the heat to the fluid F contained in the wicking structure 105 in liquid phase and transforms the fluid 118 from liquid phase into vapor phase through latent heat of evaporation,

(2) the evaporation of fluid 118 from the wicking structure 105 creates a void of the fluid 118in the liquid phase in the wicking structure 105, creating the capillary forces that draws the liquid fluid 118 through the wicking structure 105,

(3) the evaporation creates a pressure gradient comprising a higher pressure of vapor V in the vapor cavity 108 above L1 the heat source 116 and lower pressure of vapor in the vapor cavity 108 above L2 a heat sink 120 thermally coupled to the titanium substrate 102 and separated from the heat source 116,

(4) the vapor is transported T1 through the vapor cavity 108 by the pressure gradient and the vapor V condenses and returns to a liquid state above L2 the heat sink, thereby releasing the latent heat of evaporation at a location B of condensation near heat sink 120, and

(5) the condensed fluid F in the liquid state is transported T2 through the wicking structure 105 from the another region L2 that is cooler and near the heat sink 120, towards the one region A that is hotter and near the heat source 116, by the capillary forces or the acceleration-induced body forces, thereby completing a thermal transport cycle.

The fluid F (e.g., water) can be selected, and the channels 104 and vapor cavity can be formed to have one or more dimensions w, g and one or more compositions (e.g, NST) in contact with the fluid such that a thermal conductivity of the thermal ground plane is at least 100 Watts per milliKelvin at a temperature gradient of at least 50 degrees Celsius.

The thermal ground plane, or dimensions of the first and second substrates, are scaleable from 1 cm by 1cm up to 40 cm by 40 cm, and a heat flux capacity of the thermal ground plane can be tunable based on a volume of the working fluid inside of the thermal ground plane.

A thickness t of the first titanium substrate 102 can be reduced to match thermally induced stresses of the titanium substrate with a semiconductor device thermally coupled to the titanium substrate (e.g., the thickness t can be less than 100 micrometers).

Advantages of the Present Invention

Titanium provides several material properties that are desirable in terms of fracture toughness, strength-to-weight ratio, corrosion resistance, and bio-compatibility. For example, titanium has a fracture toughness almost ten times that of diamond, and over 50 times that of silicon. Further, titanium is easily machined on both a macro and micro scale. The invented pulsed laser micro-welding packaging technique on titanium makes to scale up the Ti-based TGP easily from less than 1 cm or even greater than 40 cm.

Further, titanium can be oxidized to form NST, which can increase the hydrophilicity of the wicking structure, and can be electroplated with various materials to increase the thermal conductivity of the wicking structure, which provides for extreme design flexibility in the design of the wicking structure properties and characteristics.

Because titanium has a high fracture toughness, low coefficient of thermal expansion compared to other metals, and a low modulus of elasticity, the structure 100 can be manufactured to comply thermally and physically with a large number of devices, including semiconductor devices, and the control of the dimensions and materials used within wicking structure 105 allows for engineering of the performance of the wicking structure 105 for a wide range of applications.

However, the low thermal conductivity of titanium as compared to other materials, e.g., copper, gold, silicon carbide, etc., has previously made titanium a poor choice for use as a heat transfer mechanism or as a thermal ground plane. Peer review of the present invention, when proposed as a research project, resulted in a rejection of the use of titanium as unpractical in thermal ground plane applications. However, the present invention shows that despite the low thermal conductivity of titanium, the use of micro-channels 104, various composite materials within the wicking structure 105, the controllability of fabricating different depth, width, spacing (or gap), and pitch of the channels 104 within the plurality of channels, and the invented reliable packaging technique on titanium allows titanium to overcome the previously thought of deficiencies.

The NST forming process can be modified to upgrade the hydrophilic property of the channels. The formed NST makes the surface of the channels to be supper hydrophilic and increases the wetting velocity of the working fluid inside of the channels.

The invented packaging method uses a millisecond YAG pulsed laser to micro-weld the wicks plane to the substrate. The applied packaging technique is fast, precise, inexpensive and scalable.

### REFERENCES

The following reference is incorporated by reference herein:

[1] “Titanium Inductively Coupled Plasma Etching” by E. R. Parker, et al., J. Electrochem. Soc. 152 (2005) pp. C675-83.

### CONCLUSION

One or more embodiments of the present invention describe titanium-based thermal ground planes. A thermal ground plane in accordance with one or more embodiments of the present invention comprises a titanium substrate comprising a plurality of channels, wherein the plurality of Ti channels is oxidized in certain way to form nanostructured titania coated the channels, and a vapor cavity, in communication with the plurality of titanium channels, for transporting thermal energy from one region of the thermal ground plane to another region of the thermal ground plane. Such a thermal ground plane further optionally comprises the titanium substrate that can optionally be thinned in at least part of an area of the substrate opposite the plurality of channels, the vapor cavity being enclosed using a second substrate (which can optionally be constructed from titanium), the plurality of titanium channels being formed using optionally titanium wet etching, at least one characteristic of the plurality of channels can be controlled and optionally varied within the plurality of channels to adjust a thermal transport of the thermal ground plane, and the at least one characteristic being selected from a group comprising a depth, a width, a spacing (or a gap), an amount of oxidation, a pitch of the plurality of channels, and a composition of material(s) which may include but is not limited to Ti, TiO₂, Au, or Cu applied to the channels surface to control surface physical properties including wettability.

A method of forming a thermal ground plane in accordance with one or more embodiments of the present invention comprises etching a titanium substrate to form a plurality of titanium channels, oxidizing the titanium substrate to form nanostructured titania on the plurality of titanium channels, and forming a vapor cavity in contact with the plurality of titanium channels.

Such a method further optionally comprises the titanium substrate that can optionally be thinned in at least part of an area of the substrate opposite the plurality of channels, the vapor cavity being enclosed using a second substrate (which can optionally be constructed from titanium), the plurality of titanium channels being formed using titanium inductively-wet etching, at least one characteristic of the plurality of channels being controlled and optionally varied to adjust a thermal transport of the thermal ground plane, and the at least one characteristic being selected from a group comprising a depth, a width, a spacing (or gap), an amount of oxidation, a pitch of the plurality of channels, and a composition of material(s) which may include but is not limited to Ti, TiO₂, Al, Pt, Au, or Cu applied to the channels surface to control surface physical properties including wettability.

This concludes the description of the preferred embodiment of the present invention. The foregoing description of one or more embodiments of the invention has been presented for the purposes of illustration and description. It is not intended to be exhaustive or to limit the invention to the precise form disclosed. Many modifications and variations are possible in light of the above teaching. It is intended that the scope of the invention be limited not by this detailed description, but rather by the claims appended hereto.

What is claimed is:

1. A thermal ground plane, comprising:
a titanium substrate comprising a plurality of channels, forming a wicking structure;
a vapor cavity, in communication with the plurality of titanium channels; and
a fluid contained within the wicking structure and vapor cavity for transporting thermal energy from one region of the titanium substrate or thermal ground plane to another region of the titanium substrate or thermal ground plane, wherein the fluid is driven by capillary forces or acceleration-induced body forces within the wicking structure.

2. The thermal ground plane of claim 1, in the wicking structure, a channel in the plurality of channels comprises dimensions of 1˜500 μm depth, 1˜5000 μm width and spacing between the channels of 1˜500 μm.

3. The thermal ground plane of claim 1, wherein, as heat is generated by a heat source thermally coupled to the one region of the titanium substrate:
(1) the wicking structure transfers the heat to the fluid contained in the wicking structure in liquid phase and transforms the fluid from liquid phase into vapor phase through latent heat of evaporation,
(2) the evaporation of the fluid from the wicking structure creates a void of the fluid in the liquid phase in the wicking structure, creating the capillary forces that draw the fluid through the wicking structure,
(3) the evaporation creates a pressure gradient comprising a higher pressure of vapor in the vapor cavity above the heat source and lower pressure of vapor in the vapor cavity above a heat sink thermally coupled to the titanium substrate and separated from the heat source,
(4) the vapor is transported through the vapor cavity by the pressure gradient and the vapor condenses and returns to a liquid state above the heat sink, thereby releasing the latent heat of evaporation at a location of condensation near heat sink, and
(5) the condensed fluid in the liquid state is transported through the wicking structure from the another region that is cooler and near the heat sink, towards the one region that is hotter and near the heat source, by the capillary forces or the acceleration-induced body forces, thereby completing a thermal transport cycle.

4. The thermal ground plane of claim 1, wherein the channels and vapor cavity have one or more dimensions and one or more compositions in contact with the fluid, such that a thermal conductivity of the thermal ground plane between the one region and the another region is at least 100 Watts per milliKelvin at a temperature gradient of at least 50 degrees Celsius between the one region and the another region.

5. The thermal ground plane of claim 1, further comprising a second titanium substrate, wherein the vapor cavity is enclosed by the titanium substrate and the second titanium substrate.

6. The thermal ground plane of claim 1, wherein the titanium channels in the wicking structure are oxidized to form Nano Structured Titania (NST) on a surface of the channels.

7. The thermal ground plane of claim 5, wherein:
the second titanium substrate is a titanium vapor cavity substrate backplane, and
the second titanium substrate is hermetically-sealed to the wicking structure by a pulsed laser micro-welding packaging technique.

8. The thermal ground plane of claim 1, wherein at least one characteristic of each channel in the plurality of channels is controlled to adjust the transport of thermal energy within the thermal ground plane.

9. The thermal ground plane of claim 8, wherein the at least one characteristic is selected from a group comprising:
a height of each channel in the plurality of channels, a depth of each channels in the plurality of channels, a spacing between each channel in the plurality of channels, an amount of oxidation of each channel in the plurality of channels, and a pitch of each channel in the plurality of channels.

10. The thermal ground plane of claim 9, wherein the at least one characteristic of each channel in the plurality of channels is varied within the plurality of channels.

11. The thermal ground plane of claim 1, wherein at least a portion of the channels in the plurality of channels comprises a composite of titanium with a thermally conductive material.

12. The thermal ground plane of claim 1, wherein at least a portion of the channels in the plurality of channels comprises a composite of titanium with at least one metal selected from gold and copper.

13. The thermal ground plane of claim 5, wherein:
titanium feedthroughs are fabricated on the Titanium thermal ground plane,
the titanium feedthroughs, of the second titanium substrate, are hermetically welded to the titanium substrate by pulsed laser micro-welding, and
the second titanium substrate is a backplane and the titanium substrate is a wick plane.

14. The thermal ground plane of claim 1, wherein the thermal ground plane is scaleable from 1 cm by 1 cm up to 40 cm by 40 cm, and a heat flux capacity of the thermal ground plane is tunable based on a volume of the fluid inside of the thermal ground plane.

15. The thermal ground plane of claim 1, wherein a thickness of the titanium substrate is reduced to match thermally induced stresses of the titanium substrate with a semiconductor device thermally coupled to the titanium substrate.

16. The thermal ground plane of claim 1, wherein the thickness is less than 100 micrometers.

17. The thermal ground plane of claim 1, wherein the channels comprise a rectangular cross-section with a rectangular opening at the top, extending from one side of the thermal ground plane to another side of the thermal ground plane.

18. A method for making a thermal ground plane, comprising:
forming a plurality of titanium channels on a titanium substrate of the thermal ground plane;
thermally coupling a vapor cavity with the plurality of titanium channels;
containing a fluid within the vapor cavity and the titanium channels; and
transporting thermal energy from one region of the titanium substrate to another region of the titanium substrate by driving the fluid within the plurality of titanium channels with capillary motion or acceleration-induced body force.
